(19) United States
(12) Patent Application Publication
(10) Pub. No.: US 2012/0319710 A1
(43) Pub. Date: Dec. 20, 2012

(54) METHOD AND APPARATUS FOR IMPLEMENTING PROBES FOR ELECTRONIC CIRCUIT TESTING

(75) Inventors: Krzysztof DABROWIECKI, Fremont, CA (US); Scott CLEGG, Scottsdale, AZ (US)

(73) Assignee: ProbeLogic, Inc., San Jose, CA (US)

(21) Appl. No.: 13/160,851

(22) Filed: Jun. 15, 2011

(51) Int. Cl. G01R 1/067; H01R 43/00; G01R 31/00

(52) U.S. Cl. 324/750.16; 324/755.1; 324/755.05; 29/825

(57) ABSTRACT

Disclosed is an improved probe having a spring portion which allows effective contact with a device under test without requiring a lower die portion. The probe includes a slot retention and placement portion, which provides for an improved approach for manufacturing arrangements of probes, where the slot retention and placement portions of the probe facilitate precise placement and alignment of the probes while not excessively increasing the cost or complexity of the probes and probe cards.

### FIELD OF INVENTION

Various embodiments of the invention relate to a method and an apparatus for implementing probes for electronic circuit testing.

### BACKGROUND

Testing a semiconductor device has been proven to be crucial to ensure the efficient manufacturing of the semiconductor device. Testing semiconductor devices before these semiconductor devices are individually cut and mounted in semiconductor device packages, such as an integrated circuit (IC) packaging, has shown even more advantages of saving additional cost and time for further processing the semiconductor devices or cutting and mounting these devices in semiconductor device packages.

Probe cards or similar testing devices are frequently used in testing the semiconductor devices under test. A probe card constitutes an interface between the semiconductor device under test and the testing equipment such as a metrology tool. One of the functions of a probe card is to provide electrical connectivity between the numerous bond pads and the corresponding electrical contacts of a printed circuit board (PCB), which may be external or internal to the probe card, to transmit and receive signals for testing of the semiconductor device under test.

A probe is the physical device on the probe card which provides contact to the semiconductor device under test. Due to various reasons such as alignment, manufacturability, or cost effectiveness of the probe card, probe cards often comprise an interposer or “lower die” which acts as an interface or an interconnect among the various bond pads with a much finer pitch on the device side and a different, often coarser, pitch among various electrical contacts on the “upper die” on the PCB side. That is, each of these probe cards comprises an interposer or at least a substrate that acts as an interposer to interface between the semiconductor device under test and the PCB so as to ensure the proper test signals are transmitted and received from the corresponding bond pads on the semiconductor device under test.

However, modern semiconductor devices with high density bond pads introduces difficult issues and challenges to testing devices such as probe cards described above. With the continual shrinkage of feature sizes and die sizes, the pitch of the bond pads has become smaller, and thus the spacing of the probes and interconnects between the probes and the PCB have also become smaller as a result. The ever decreasing spacing and pitch cause new challenges to properly configure and insulate various components of the probe card when there is a need to properly implement and precisely configure the probes using both an upper die and a lower die. In addition, the probe cards are more expensive to manufacture and calibrate if there is a need to implement both an upper die and a lower die.

There are known approaches to implement probe cards without using a lower die. For example, one known approach is to implement probes in a cantilever fashion. In this approach, the probe is fixedly secured on a substrate with the probe extended in a cantilever shape towards the device under test. To allow the probe to sufficiently handle the stresses placed the probe during testing, particularly during a scrubbing action, the height of the probe that extends from the substrate to the device under test must necessarily be very small. As a result, this greatly increases the possibly of interference created by debris collected between the substrate and the device under test. In addition, alternative approaches to implement spring-based probes have the problem that they are intended to induce lateral movement during operation of the probe cards.

Yet another problem faced by manufacturers of probe cards is the proper alignment of the probes within the probe cards. In the past, manufacturers needed to resort to implementation of complex multi-component structures to ensure the proper alignment of probes within probe cards. For example, one approach is to use a retention arrangement that include multiple plates having configured openings to properly place and align the probes. In addition, lower dies may be implemented to align and place the probes. As noted above, one problem with these arrangements is that using these additional components to place and align the probes increases the cost and complexity of the probe cards. Moreover, these complex arrangements make it very difficult to replace a faulty probe once the prober car has been fully manufactured.

Therefore, there is a need for an improved probe which addresses the shortcomings of the prior probe card implementations. There is also the need for an improved approach for manufacturing arrangements of probes, which allow for precise placement and alignment of the probes while not excessively increasing the cost or complexity of the probes and probe cards.

### SUMMARY

Some embodiments of the present invention are directed to an improved probe having a spring portion which allows effective contact with a device under test without requiring a lower die portion. Some embodiments of the invention also relate to a probe having a slot retention and placement portion, which provides for an improved approach for manufacturing arrangements of probes, where the slot retention and placement portions of the probe facilitate precise placement and alignment of the probes while not excessively increasing the cost or complexity of the probes and probe cards.

Further details of aspects, objects, and advantages of the invention are described below in the detailed description, drawings, and claims. Both the foregoing general description and the following detailed description are exemplary and explanatory, and are not intended to be limiting as to the scope of the invention.

### BRIEF DESCRIPTION OF THE FIGURES

The drawings illustrate the design and utility of preferred embodiments of the present invention. It should be noted that the figures may not be drawn to scale, and that elements of similar structures or functions may be represented by like reference numerals throughout the figures. In order to better appreciate how the above-recited and other advantages and objects of the present inventions are obtained, a more particular description of the present inventions briefly described above will be rendered by reference to specific embodiments thereof, which are illustrated in the accompanying drawings. Understanding that these drawings depict only typical embodiments of the invention and are not therefore to be considered limiting of its scope, the invention will be described and explained with additional specificity and detail through the use of the accompanying drawings in which:

FIG. 1 illustrates a probe according to some embodiments of the invention.

FIG. 2 illustrates installation of a probe into a mounting substrate.

FIG. 3 shows an example arrangement of probes on a testing apparatus.

FIG. 4 shows an example arrangement of probes with their corresponding slots.

FIG. 5 shows an example arrangement of slots corresponding to the probes of FIG. 3.

FIG. 6 shows an example dimensions and angles for an illustrative probe.

FIG. 7 illustrates an alternate approach for implementing a probe arrangement.

### DETAILED DESCRIPTION

Some embodiments of the present invention are directed to an improved probe having a spring portion which allows effective contact with a device under test without requiring a lower die portion. Some embodiments of the invention also relate to a probe having a slot retention and placement portion, which provides for an improved approach for manufacturing arrangements of probes, where the slot retention and placement portions of the probe facilitate precise placement and alignment of the probes while not excessively increasing the cost or complexity of the probes and probe cards.

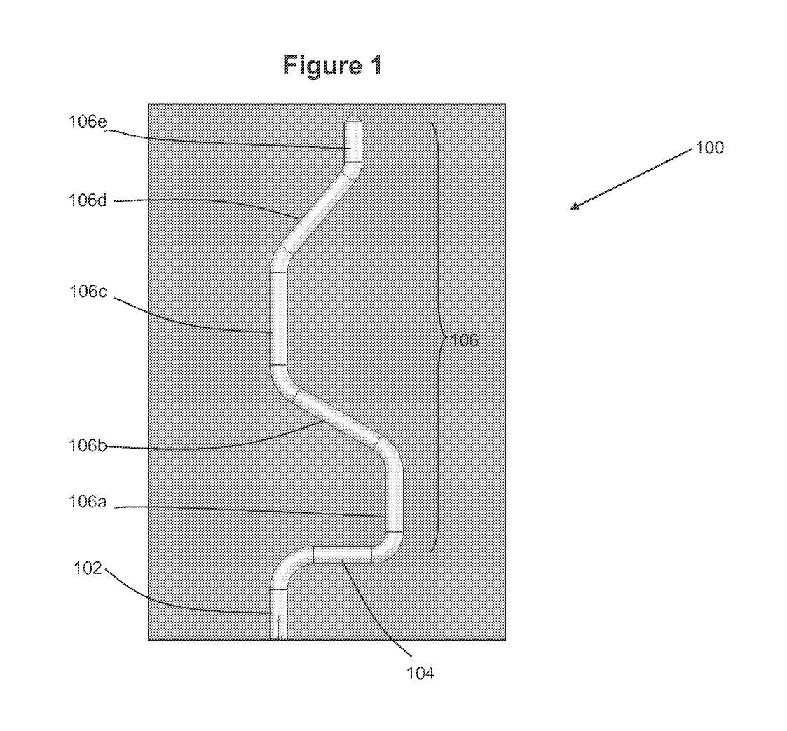

FIG. 1 illustrates a side view of a probe 100 according to some embodiments of the invention. In the embodiment of FIG. 1, probe 100 comprises a spring member 106, a slot retention and placement portion 104, and an elongated member 102.

When the probe 100 is properly mounted on a mounting substrate, spring member 106 comprises the part of the probe 100 which generally extends from the mounting substrate towards the device under test. Spring member 106 is configured such that during operation of the probe card, a spring action is formed in the vertical direction with spring member 106 by contact of the probe 100 with the device under test.

Spring member 106 comprises a first extending arm 106a, a first angled arm 106b, a second extending arm 106c, a second angled arm 106d, and a contact arm 106e. The contact arm 106e is the portion of spring member 106 which provides contact to a device under test. The configuration of the first extending arm 106a, first angled arm 106b, second extending arm 106c, and second angled arm 106d provide for the height and spring/contact properties of the spring member 106.

It is the spring force provided by the spring member 106 that allows probe to be mounted onto a mounting substrate without requiring an additional lower die. Recall from the background description that a lower die is typically required in a probe card to ensure proper location of probes and to keep probes adequately centered in lateral directions during operation of the probe card. With the configuration of the present probe, even in the absence of a lower die, the spring member 106 provides sufficient spring force such that the probe is very resistant to excessive lateral movements and the spring force and positioning of the spring member components also allows the contact arm 106e to be firmly placed at its proper location relative to an underlying device under test. This allows for very precise control over the later deflection of the tip (contact arm 106e) of the probe 100, particularly during operation of the probe card when scrubbing is performed.

According to some embodiments, the portions of spring member 106 are configured to provide a balance of moments such that there is no moment arm at the contact arm 106e. This allows for maintenance and balance of horizontal and lateral forces as the probe is utilized to contact with and scrub across the device under test. In the embodiment of FIG. 1, the material choice, diameter sizes, arm lengths, and arm angles is selected to provide for this balancing of moments. In some embodiments of the invention, the probe is constructed of gold plated tungsten wire with a size that is less than or equal to 0.002 inches.

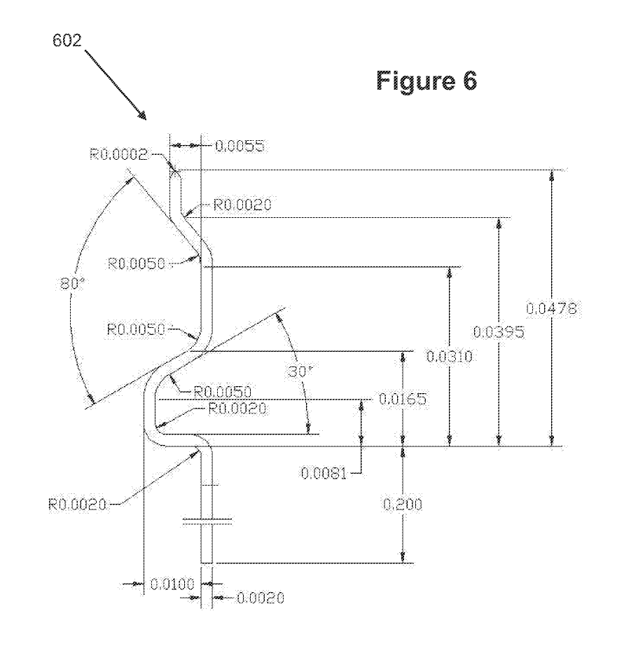

FIG. 6 illustrates dimensions and angles for an example probe 602. Of course, these identifications of dimensions, angles, and materials are for purposes of illustration only, and other materials, dimensions, and angles are well within the scope of the present invention. According to one embodiment, the probes are manufactured by bending wires of the appropriate thickness into the desired shapes and geometries. According to an alternate embodiment, an etching processes is used to manufacture the probes. Yet another possible embodiment is to use a photolithographic plating process to manufacture the probe structure.

The height provided by the spring member 106 permits operation of the probe 106 in a probe card while preventing excessive interference from debris that may collect among the probes. The spring member 106 may be configured to have any suitable height, subject to proper choice and configuration of the materials, arm lengths, and angles to ensure that the probe height does not negatively affect the desired spring properties of the probe 106.

The contact member 106e comprises a probe tip which is formed of any suitable shape and/or dimension, e.g., having a domed, spherical, flat, pointed, diamond, cylindrical, and/or wedged shaped tip. The probes with the appropriately shaped tip may be used to break through the oxide layer on or near the contact area on the bond pads if it is needed in some embodiments.

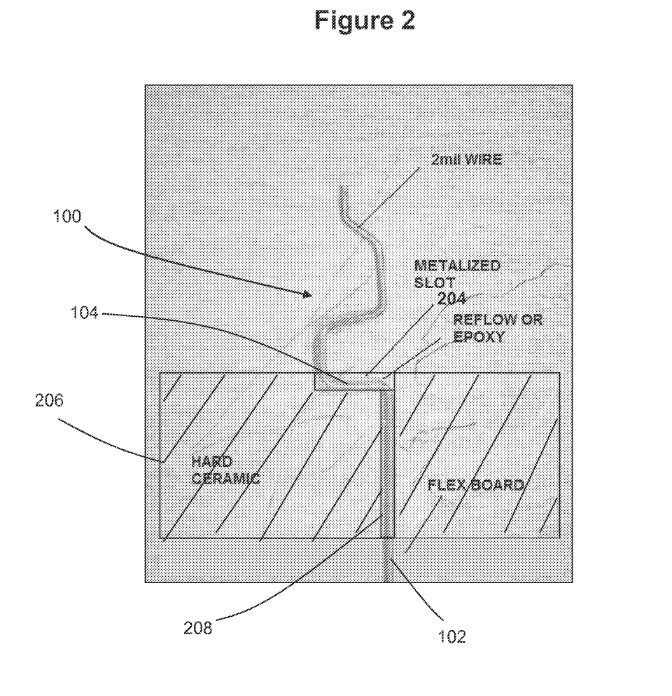

The probe 100 is mounted onto a mounting substrate using the elongated member 102 and the slot retention and placement portion 104. This aspect of the current embodiment of the invention can best be seen in FIG. 2, which shows the probe 100 along with a cross sectional view of a mounting substrate 206.

The elongated member 102 provides for positional accuracy when installing the probe 100 into a probe card. The elongated member 102 has sufficient length to extend through an aperture 208 in the mounting substrate 206. In some embodiments, the apertures 208 within the mounting substrate 206 is configured to match the pattern of bond pads on the semiconductor device under test and/or to align the apparatus and/or the assembled probes to align with the corresponding bond pads on the semiconductor device under test. The elongated member 102 can be configured with any suitable length or diameter as needed to provide electrical contact with the underlying probe card circuitry.

The slot retention and placement portion 104 provides for directional accuracy of the probe 100. The slot retention and placement portion 104 fits within slot 204 to precisely align the probe 100 in its proper direction and angle. The width of slot 204 is manufactured to match the diameter of the slot retention and placement portion 104 of probe 100.

It is the fitment of the slot retention and placement portion 104 into slot 204 that allows for the improved efficiency of manufacturing for probe cards that include probes 100. Instead of merely using just the elongated member 102 itself to mount the probe 100, the additional usage of using the slot retention and placement portion 104 to align within the slot 204 provides a way to mechanically ensure precise alignment of the probe 100 in its proper direction. This approach is not only highly effective, but is very cost-effective. This is in contrast to the conventional approaches that use costly external tooling to ensure proper alignments of probes.

One key advantage of this arrangement is that it greatly facilitates the ability of a technician to make repairs on individual probes of a probe card, e.g., to install a replacement probe into a probe card. This is because even on an individual basis, the probes can be installed with great confidence that it will be precisely aligned in the proper direction and angle. This is unlike conventional approaches which utilize installation of probes on a monolithic basis to ensure coordinated alignment of the probes.

According to some embodiments, the probe 100 comprises a gold plated tungsten material, or gold plated tungsten alloys such as the rhenium tungsten alloy, with wire diameters manufactured with a range from between 0.002″ and 0.0015″. Other suitable materials in addition to tungsten may also be employed as well. For example, materials such as BeCu, Ni alloys, Co, and Pt alloys may also be used. The probe 100 may also be formed of extruded metal or metallic wires, e.g., at a nominal diameter of one to two micro meters, or even larger at a larger nominal diameter ranging from two micro meters to 100 micro meters.

The probes may be made from multiple segments of metal or metallic sub-components such as metal or metallic wires or components of different sizes between the probe tip and the end of the probe that is connected to the printed circuit board. The probes may be manufactured with a circular cross-section, or with any other suitable shape such as a rectangular cross-sectional shape.

In some embodiments, the probes may be made a single piece of extruded wire or component with the same size. For example, a probe may be made from a single piece of extruded wire from the tip of the probe to the end where the probe is connected to the printed circuit board. In these embodiments, the manufacturing of the probes is greatly simplified because it only involves simple manufacturing steps such as cutting, bending, sanding, and/or grinding of a small diameter extruded wire. Furthermore, the cost of the probe is greatly reduced in these embodiments because of the use of a single, extruded wire which is readily available and is more manufacturable than a probe with multiple, differently sized components.

In some embodiments, the probe is designed in such a way that the compressive stress on the tip is high enough to break an oxide of the bond pad material and bump material (hereinafter bump and bond pads collectively referred to as bond pads) to ensure sufficiently good contact between the probe and its corresponding bond pad on the semiconductor device under test. The material, geometric configuration which comprises the size and form of the probe, and/or the tip of the probe, and the manner in which the probes are engaged with their corresponding bond pads may be properly considered to ensure good electrical contact between the probes and their corresponding bond pads. This is important for testing which requires higher current to the semiconductor device under test because the higher current will cause more Ohm heating if the electrical contact resistance is not properly managed. This is especially important for testing semiconductor device under test with very high pad density because such a semiconductor device under test usually requires probes with small geometries, such as a few microns in diameter, and thus inevitably increases the resistance of the probe and hence the Ohm heating when the testing runs current through such higher resistance probes. Lower electrical contact resistance will reduce the amount of Ohm heating and thus protect not only the probes but also the semiconductor devices under test.

The mounting substrate 206 is made of an electrically insulating material such as a hard ceramic, which is backed with a material such as flex board. The electrically insulating material for the body of the upper die 206 can also comprise a fire rated electrical-grade, dielectric fiberglass laminate epoxy resin, such as a G10-FR4.

In some embodiments, the slot retention and placement portion 104 is affixed within slot 204 using an adhesive such as epoxy resin. If the slot retention and placement portion 104 is affixed within the slot 204 using adhesives that rely upon a metalized surface, then the slot 204 can be configured to comprise a metalized slot. The length of slot 204 can be selected to suitably ensure proper alignment of the probe 100.

During assembly, probe card is assembled by running each of elongated members 102 of the probes 100 through its corresponding apertures 208 in the mounting substrate 206. In some embodiments, a transparent or translucent material may be selected such that the assembler is allowed to see through the materials for the ease of assembly or manufacturing of the apparatus. The elongated member 102 extends through the mounting substrate 206 to attach to a printed circuit board (not shown) which comprise the testing circuitry. The probes 100 may be electrically or operatively connected to the printed circuit board by, for example, the use of some wire solder. The exemplary apparatus may further comprise some probe securing mechanism which is used to secure the probes 100, e.g., using epoxy resin or other similar adhesives.

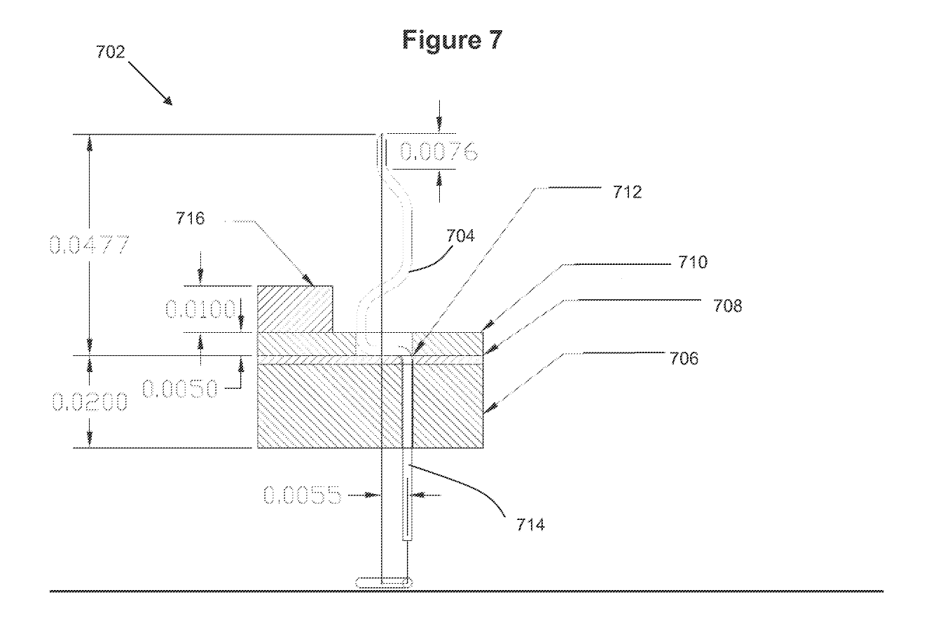

FIG. 7 illustrates a cross-sectional view of an alternate probe mounting assembly 702. Probe mounting assembly 702 includes a base 706, e.g., a base made of ceramic material. However, the probe mounting assembly further includes a layer 708 having conductive traces to transmit electrical signals from probe 704 to external probe card circuitry. In some embodiments, the layer 708 comprises a Kapton™ film material that is formed to include electrically conducting/metallic traces. In this way, electrical signals are transferred though traces on the layer 708 along the side of the probe assembly, rather than vertically along the lower elongated portion 714 of probe 704.

An upper layer 710 is placed over the layer 708 that include the conductive traces. In some embodiments, upper layer 710 comprises a dielectric or non-conductive polymer material. According to one embodiment, upper layer 710 comprises a Kapton™ polymide material. The slot 712 to hold probe 704 is formed in the upper layer 710's material, e.g., using a chamfer approach.

A constraining object 716 may be employed to press down upon upper layer 710. Constraining object may be implemented as a plate in some embodiments, although other approaches may also be employed to constrain 710 and 708. Plate 716 may be needed, for example, in configurations where the materials utilized for upper layer 710 is prone to non-uniform thickness characteristics.

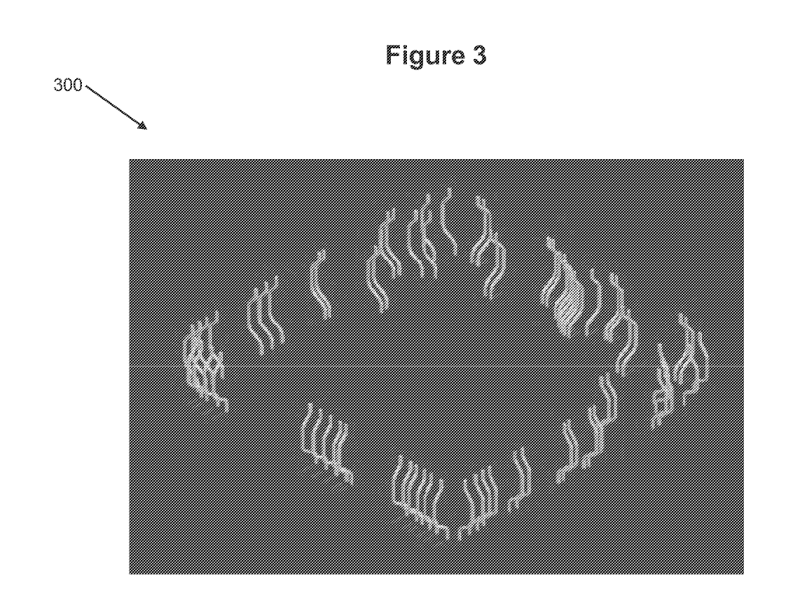

Multiple probes may be arranged in an array of probes on a testing apparatus. FIG. 3 shows an example configuration 300 of multiple probes that have been mounted on a testing apparatus.

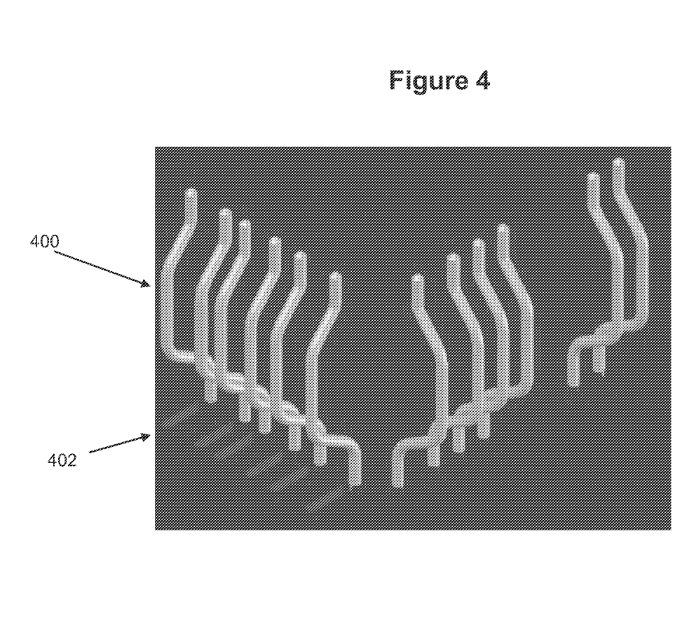

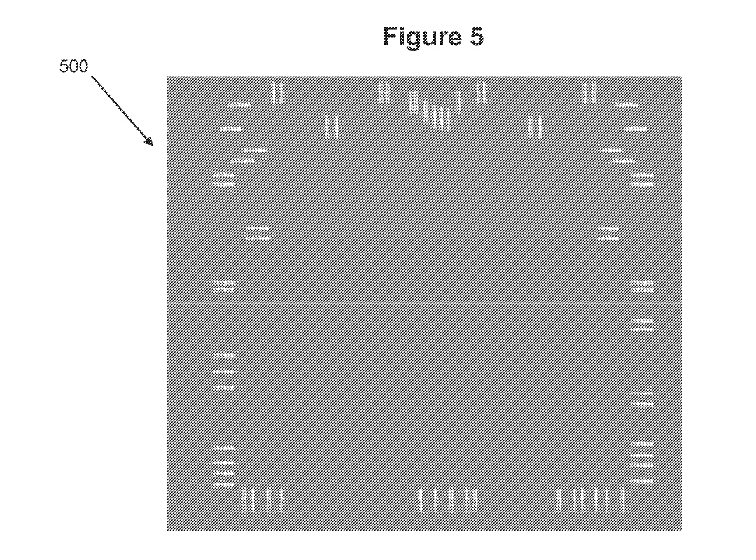

The length of the slots can be changed and configured for placing the probes. This allows, for example, the probes to be placed into staggered arrangements on the testing apparatus. FIG. 4 shows a set of probes 400 that have been installed in a staggered configuration where the slots 402 have different sizes, angle parameters, and/or space allocations. The advantage of allowing different configurations for the slots is that this permits more flexibility in where the probes can be advantageously located on the testing apparatus. FIG. 5 shows an example arrangement of slots at different locations and angles to accommodate the probe arrangement 300 of FIG. 3.

Therefore, what has been described is an improved approach for implementing probes and the manufacture of testing apparatuses. An improved probe is described in some embodiments which has a spring portion that allows for effective contact with a device under test without requiring a lower die portion. The improved probe in some embodiments comprises a slot retention and placement portion, which provides for an improved approach for manufacturing arrangements of probes, where the slot retention and placement portions of the probe facilitate precise placement and alignment of the probes while not excessively increasing the cost or complexity of the probes and probe cards.

In the foregoing specification, the invention has been described with reference to specific embodiments thereof. It will, however, be evident that various modifications and changes may be made thereto without departing from the broader spirit and scope of the invention. The specification and drawings are, accordingly, to be regarded in an illustrative rather than restrictive sense.

The aforementioned embodiments are described for the ease of illustration and explanation but do not intend to and shall not be construed to limit the scope of various embodiments. Modification and substitution may also be made by one of ordinary skill in the art without departing from the spirit or scope of the invention, which should still be deemed to be within the scope as set forth by the claims. Other aspects and features of the invention will be evident from reading the following detailed description of the preferred embodiments, which are intended to illustrate, not limit, the invention. Although particular embodiments of the present inventions have been shown and described, it will be understood that it is not intended to limit the present inventions to the preferred embodiments, and it will be obvious to those skilled in the art that various changes and modifications may be made without departing from the spirit and scope of the present inventions. The specification and drawings are, accordingly, to be regarded in an illustrative rather than restrictive sense. Various embodiments are intended to cover alternatives, modifications, and equivalents, which may be included within the spirit and scope of the present inventions as defined by the claims.

What is claimed is:

1. A probe for testing of a semiconductor device, comprising:
an elongated member having a length sufficient to extend within an aperture of a mounting substrate;
a slot placement portion, wherein the slot placement portion is shaped to fit within a slot on the mounting substrate; and
a contact portion having a contact member at a tip of the contact portion, the contact member configured to engage a device under test.

2. The probe of claim 1 in which the contact portion comprises a spring member.

3. The probe of claim 2 in which the spring member further comprises a first extending arm, a first angled arm, a second extending arm, and a second angled arm.

4. The probe of claim 2 in which the spring member provides a spring force when engaged against the device under test.

5. The probe of claim 4 in which the spring member resists lateral deflection.

6. The probe of claim 2 in which the spring member provide balancing of moment arms at the contact member.

7. The probe of claim 1 in which the contact portion comprises tungsten or a tungsten alloy material.

8. The probe of claim 1 in which the contact member comprises a dome, spherical, or wedge shape.

9. The probe of claim 1 in which the slot placement portion extends substantially at a right angle from the elongated member.

10. The probe of claim 1 in which the slot placement portion is configured to fit within a slot on the mounting substrate to provide directional alignment for the probe.

11. The probe of claim 1 in which the probe is mounted in a probe mounting assembly having a mounting layer having a conductive trace, such that the conductive trace is used to electrically connect the probe with external circuitry.

12. The probe of claim 1 in which the probe is mounted on the mounting substrate such that the elongated member extending through the mounting surface is used to electrically connect the probe with external circuitry.

13. A method of manufacturing a testing apparatus comprising an array of probes, the method comprising:
inserting a probe into a mounting substrate on the testing apparatus, in which the probe comprises a slot placement portion, and wherein the slot placement portion is shaped to fit within a slot on the mounting substrate; and
affixing the probe to the mounting substrate.

14. The method of claim 11 in which an epoxy resin within the slot is used to affix the probe to the mounting substrate.

15. The method of claim 11 in which an elongated member on the probe is inserted into an aperture on the mounting substrate, where the elongated member provides for positional alignment of the probe and the slot placement portion provides for directional alignment of the probe.

16. The method of claim 11 in which the probe is inserted as a replacement for an existing probe.

17. The method of claim 11 in which multiple probes are inserted into the testing apparatus in a staggered arrangement.

18. The method of claim 11 in which multiple probes are inserted into the testing apparatus, and some of the multiple probes correspond different slot configurations.

19. The method of claim 11 in which the slot comprises a metalized slot.
